(19) United States
(12) Patent Application Publication
(10) Pub. No.: US 2009/0202793 A1
(43) Pub. Date: Aug. 13, 2009

(54) Photosensitive, Aqueous Alkaline Solution-Soluble Polyimide Resin and Photosensitive Resin Composition Containing the same

(75) Inventors: Ryutaro Tanaka, Tokyo (JP); Makoto Uchida, Tokyo (JP)

Correspondence Address: Nields, Lemack & Frame, LLC, 176 E. Main Street, Suite #5, Westborough, MA, 01581, US

(73) Assignee: NIPPON KAYAKU KABUSHIKI KAISHA

(21) Appl. No.: 12/309,059

(22) PCT Filed: Jul. 9, 2007
(86) PCT No.: PCT/JP2007/063646

§ 371 Date: Jan. 5, 2009

(30) Foreign Application Priority Data
Jul. 11, 2006 (JP) 2006-190177

(51) Int. Cl. B32B 3/10; C08G 73/10; G03F 7/004; G03F 7/039

(52) U.S. Cl. 428/195.1; 528/310; 430/280.1; 430/270.1

(57) ABSTRACT

The present invention relates to a photosensitive, aqueous alkaline solution-soluble polyimide resin (A) obtained by reacting a polyimide resin (a) which can be obtained by a tetracarboxylic acid dianhydride with a diamine compound with an energy ray-curing type aqueous alkaline solution-soluble resin (b); the resin has excellent photosensitivity obtained by mixing with a photopolymerization initiator and the like; the obtained cured products can be photosensitive resin compositions excellent in flexibility, low warping property, adhesion properties, solvent resistance, acid resistance, heat resistance, gold plating resistance and the like.

### TECHNICAL FIELD

The present invention relates to a photosensitive, aqueous alkaline solution-soluble polyimide resin developable in an aqueous alkaline solution and a photosensitive resin composition using it and a cured product thereof. More specifically, the present invention relates to a photosensitive resin composition which imparts cured products excellent in developability, flexibility, adhesion properties, heat resistance, chemical resistance, plating resistance and the like, which are useful as solder masks and cover lays for flexible printed wiring boards, interlayer insulation films for multilayer printed wiring boards, and the like; and a cured product thereof.

### BACKGROUND ART

At present, in some printed wiring boards for consumer use and most solder masks of printed wiring boards for industrial use, photo-curing resin compositions are, in terms of high precision and high density, used which are exposed to light and then developed to form images using photolithography, and further cured finally by heat and/or photo-irradiation. Also in consideration of environmental issues, the mainstream is a liquid solder mask of an alkaline developing type using a dilute aqueous alkaline solution as a developer. In particular, flexibility is required for solder masks and cover lays applied to ball grid array (hereinafter, referred to as BGA) substrates and flexible substrates, and Patent Literature 1 proposes, as this ingredient, a composition using a compound obtained by reacting a polybasic acid anhydride with a reaction product of a polyfunctional bisphenol type epoxy resin having a flexible structure with a (meth)acrylic acid.

Patent Literature 2 proposes, for improvement of flexibility, an aqueous alkaline solution-soluble urethanated epoxy carboxylate compound obtained by reacting a reaction product of an epoxy compound having two epoxy groups in a molecule with a monocarboxylic acid compound having an ethylenically unsaturated double bond in a molecule, a carboxylic acid compound having two hydroxy groups in a molecule and a diisocyanate compound; and a composition thereof.

In addition, printed wiring boards are required to have higher precision and higher density for reduction in size and weight and improvement of transmission speed for mobile devices, involving that cover lays and solder masks are increasingly required to also have more excellent performance in solder heat resistance, electroless gold plating resistance, substrate adhesion properties, chemical resistance and the like than ever before, while keeping flexibility higher than conventionally required; and Patent Literature 3 proposes use of photosensitive polyimide.

### [Patent Literature 1] JP 2868190

### [Patent Literature 2] JP 2002-338652

### [Patent Literature 3] WO 2003/060010

### DISCLOSURE OF THE INVENTION

### Problems to be Solved by the Invention

However, using cured products of the solder mask composition disclosed in Patent Literature 1 improves surface crack resistance, but poses such a problem that their flexibility are not enough to withstand acute folding and bending. The ingredients of Patent Literature 2 have good flexibility, but have problems in heat resistance and durability compared with cover lays with a polyimide film now being used. Further, the composition of Patent Literature 3 has satisfying properties such as photosensitivity and heat resistance, but poses such problems that a relatively strong aqueous alkaline solution must be used in development, and that the cost is high.

The present invention has an object to provide a photosensitive resin composition which enables patterning fine images which can meet high functionalization of present printed wiring boards, is excellent in sensitivity to active energy rays, can be pattern-formed by developing by a dilute aqueous alkaline solution, and is suitable for solder mask inks and cover lays whose cured films have sufficient flexibility and which are excellent in heat resistance, electroless gold plating resistance, substrate adhesion properties, chemical resistance and the like; and a cured product thereof.

### Means of Solving the Problems

The present inventors have extensively studied to solve the above problems and found that a composition containing a photosensitive, aqueous alkaline solution-soluble polyimide resin can solve the above problems and then achieved the present invention. That is, the present invention relates to:

(1) A photosensitive, aqueous alkaline solution-soluble polyimide resin (A) obtained by reacting a polyimide resin (a), which is obtained by reaction of a tetracarboxylic acid dianhydride with a diamine compound, with an energy ray-curing type aqueous alkaline solution-soluble resin (b),
(2) The photosensitive, aqueous alkaline solution-soluble polyimide resin (A) according to the above (1), wherein the polyimide resin (a) is obtained by carrying out reaction of a tetracarboxylic acid dianhydride with a diamine compound in the presence of a lactone and a base as catalysts,
(3) The photosensitive, aqueous alkaline solution-soluble polyimide resin (A) according to the above (1) or (2), characterized in that the polyimide resin (a) has a phenol hydroxy group,
(4) The photosensitive, aqueous alkaline solution-soluble polyimide resin (A) according to any one of the above (1) to (3), characterized in that the energy ray-curing type aqueous alkaline solution-soluble resin (b) has a hydroxy group, an isocyanate group or a carboxy group at a terminal, or is an acid anhydride,
(5) The photosensitive, aqueous alkaline solution-soluble polyimide resin (A) according to any one of the above (1) to (4), wherein the energy ray-curing type aqueous alkaline solution-soluble resin (b) (hereinafter, referred to as resin (b)) is any of the following (1), (2) or (3):
(1) A resin (b) obtained by reacting a reaction product (c) of an epoxy compound having two epoxy groups with a monocarboxylic acid compound having an ethylenically unsaturated group, with a tetracarboxylic acid dianhydride (d);
(2) A resin (b) obtained by reacting a reaction product (c) of an epoxy compound having two epoxy groups with a monocarboxylic acid compound having an ethylenically unsaturated group, a monocarboxylic acid compound (e) having two hydroxy groups in a molecule with a diisocyanate compound (f); or
(3) A resin (b) obtained by reacting a reaction product (c) of an epoxy compound having two epoxy groups with a monocarboxylic acid compound having an ethylenically unsaturated group, with tetracarboxylic acid dianhydride (d) and then a dicarboxylic acid monoanhydride,
(6) The photosensitive, aqueous alkaline solution-soluble polyimide resin (A) according to any one of the above (1) to (5), wherein the weight average molecular weight as polystyrene is 10,000 to 400,000,
(7) A negative-type, photosensitive, aqueous alkaline solution-soluble polyimide resin composition characterized by containing the photosensitive, aqueous alkaline solution-soluble polyimide resin (A) according to any one of the above (1) to (6), a photopolymerization initiator (B), a cross-linking agent (C) as an optional component and further a curing agent (D) as an optional component,
(8) A positive-type, photosensitive, aqueous alkaline solution-soluble polyimide resin composition characterized by containing the photosensitive, aqueous alkaline solution-soluble polyimide resin (A) according to any one of the above (1) to (6) and a photoacid-generating agent (E),
(9) A cured product of the photosensitive, aqueous alkaline solution-soluble polyimide resin composition according to the above (7) or (8),
(10) A substrate having a layer of the cured product according to the above (9),
(11) A polyimide resin solution containing a photosensitive, aqueous alkaline solution-soluble polyimide resin (A) obtained by reacting a polyimide resin (a) which is obtained by reaction of a tetracarboxylic acid dianhydride with a diamine compound, with an energy ray-curing type aqueous alkaline solution-soluble resin (b), and a solvent,
(12) The polyimide resin solution according to the above (11), wherein the energy ray-curing type aqueous alkaline solution-soluble resin (b) is:
(i) A resin (b) obtained by reacting an epoxy (meth)acrylate with a tetracarboxylic acid dianhydride (d);
(ii) A resin (b) obtained by reacting an epoxy (meth)acrylate with a monocarboxylic acid compound (e) having two hydroxy groups in a molecule and a diisocyanate compound (f); or
(iii) A resin (b) obtained by reacting an epoxy (meth)acrylate with a tetracarboxylic acid dianhydride (d) and then dicarboxylic acid monoanhydride.

### EFFECT OF THE INVENTION

The photosensitive, aqueous alkaline solution-soluble polyimide resin (A) of the present invention is characterized in that it is obtained by reacting a polyimide resin (a) obtained from a tetracarboxylic acid dianhydride and a diamine compound with an energy ray-curing type aqueous alkaline solution-soluble resin (b). A polyimide solution containing this photosensitive, aqueous alkaline solution-soluble polyimide resin (A) can be made into a photosensitive resin composition by addition of a photopolymerization initiator (B) or a photoacid-generating agent (E). The photosensitive resin composition containing this photosensitive, aqueous alkaline solution-soluble polyimide resin (A), a photopolymerization initiator (B), a cross-linking agent (C) as an optional component, and a curing agent (D) as a further optional component is excellent in photosensitivity when formed into a coated film by ultraviolet ray curing and can be patterned by alkali development; and thus obtained cured products have flexibility, adhesion properties, pencil hardness, solvent resistance, acid resistance, gold plating resistance and the like which are sufficiently satisfying, and particularly high heat resistance. Resins usually used provide satisfying heat resistance by using a filler, an epoxy resin and the like, but said photosensitive, aqueous alkaline solution-soluble polyimide resin (A) can provide cured products having a highly heat resistance without using additives and a curing agent. Therefore, said photosensitive, aqueous alkaline solution-soluble polyimide resin (A) is suitable as an ingredient in a photosensitive resin composition for printed wiring boards and cover lays. In addition, this photosensitive, aqueous alkaline solution-soluble polyimide resin (A) can be mixed with a photoacid-generating agent (E) to be used also as a positive-type, photosensitive, aqueous alkaline solution-soluble polyimide resin composition.

### BEST MODE FOR CARRYING OUT THE INVENTION

The photosensitive, aqueous alkaline solution-soluble polyimide resin (A) (hereinafter, also referred to as alkali-soluble polyimide resin (A) for simplicity) of the present invention can be obtained by reacting a polyimide resin (a) obtained from a tetracarboxylic acid dianhydride and a diamine compound with an energy ray-curing type aqueous alkaline solution-soluble resin (b). When the added equivalents of polyimide resin (a) which is obtained from a tetracarboxylic acid dianhydride and a diamine compound is shown as x, the added equivalents of energy ray-curing type aqueous alkaline solution-soluble resin (b) is shown as y, the ratio of x>y leads to an excess of polyimide resin (a) and is preferably used in positive-type. On the other hand, the ratio of x<y leads to an excess of energy ray-curing type aqueous alkaline solution-soluble resin (b) and is preferably used in negative-type.

The added equivalents of tetracarboxylic acid dianhydride is shown as s and the added equivalents of diamine compound is shown as t in production of polyimide resin (a), the ratio of s>t leads to an acid anhydride at a terminal of polyimide resin (a). In this case, the energy ray-curing type aqueous alkaline solution-soluble resin (b) (hereinafter, also referred to as resin (b) for simplicity) reacted with it preferably has a hydroxy group or an isocyanate group at a terminal. When said resin (b) is terminated with a hydroxy group, said hydroxy group is reacted with an acid anhydride group at a terminal of polyimide resin (a), resulting in polymerization (esterification) of the polyimide resin (a) and said resin (b). When said resin (b) is terminated with an isocyanate group, said isocyanate group is reacted with an acid anhydride group at a terminal of polyimide resin (a), resulting in polymerization (imidization) of the polyimide resin (a) and said resin (b).

On the other hand, the ratio is s<t, the polyimide resin (a) is terminated with an amino group. In this case, the resin (b) reacted to it preferably has an acid anhydride group, an isocyanate group or a carboxy group at a terminal. When said resin (b) is terminated with an acid anhydride, the acid anhydride group at a terminal of said resin (b) is reacted with amino group at a terminal of polyimide resin (a) to form amic acid, resulting in polymerization of the polyimide resin (a) and the resin (b). When the resin (b) is terminated with an isocyanate group, the isocyanate group at a terminal of said resin (b) is reacted with an amino group at a terminal of polyimide resin (a) to form a urea bond, resulting in polymerization of the polyimide resin (a) and the resin (b). When said resin (b) is terminated with a carboxy group, the carboxy group at a terminal of said resin (b) is reacted with an amino group at a terminal of polyimide resin (a) to form an amide bond, resulting in polymerization of the polyimide resin (a) and the resin (b). In addition, in the case of polymerization by forming amic acid as described above, imidization can be also carried out by heating at 280 to 350° C. for 0.5 to 5 hours after coating on a substrate and patterning.

General reaction schemes for the above five are shown below.

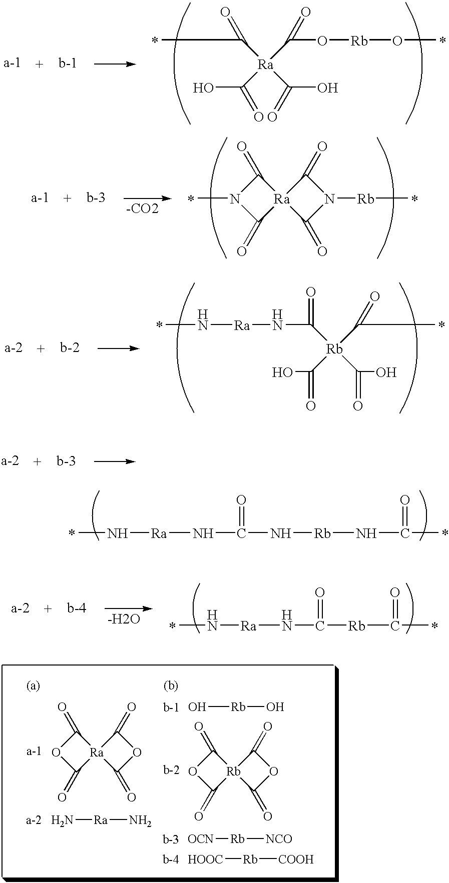

(wherein, each of Ra₁ and Rb₂ represents a tetravalent organic group, and each of Ra₂, Rb₁, Rb₃ and Rb₄ represents a divalent organic group)

Any tetracarboxylic acid dianhydride can be used for production of polyimide resin (a) as long as it has at least two acid anhydride structures in a molecule, however it is preferably a compound selected among pyromellitic acid anhydride, ethyleneglycol-bis(anhydrotrimellitate), glycerine-bis(anhydrotrimellitate)monoacetate, 1,2,3,4-butanetetracarboxylic acid dianhydride, 3,3′,4,4′-diphenylsulfonetetracarboxylic acid dianhydride, 3,3′,4,4′-benzophenontetracarboxylic acid dianhydride, 3,3′,4,4′-biphenyltetracarboxylic acid dianhydride, 3,3′,4,4′-diphenyl ether tetracarboxylic acid dianhydride, 2,2-bis(3,4-anhydrodicarboxyphenyl)propane, 2,2-bis(3,4-anhydrodicarboxyphenyl)hexafluoropropane, 5-(2,5-dioxotetrahydro-3-furanyl)-3-methylcyclohexene-1,2-dicarboxylic acid anhydride, 3a,4,5,9b-tetrahydro-5-(tetrahydro-2,5-dioxo-3-furanyl)-naphtho[1,2-c]furan-1,3-dione, 1,2,4,5-cyclohexanetetracarboxylic acid dianhydride, and bicyclo(2,2,2)-octo-7-ene-2,3,5,6-tetracarboxylic acid dianhydride.

The tetracarboxylic acid dianhydride is preferably an aromatic tetracarboxylic acid dianhydride. More preferably is an aromatic tetracarboxylic acid dianhydride having 1 to 2 benzene rings: if it has a benzene ring, it has two anhydride groups on the benzene ring; and if it has two benzene rings, the two benzene rings having an acid anhydride group are bonded directly or through a cross-linking group, or as a condensed ring. The cross-linking group is preferably —O—, —CO—, —SO₂— or the like.

More preferably are pyromellitic acid anhydride, 3,3′,4,4′-diphenylsulfonetetracarboxylic acid dianhydride, 3,3′,4,4′-benzophenontetracarboxylic acid dianhydride, 3,3′,4,4′-biphenyltetracarboxylic acid dianhydride, 3,3′,4,4′-diphenyl ether tetracarboxylic acid dianhydride and the like, and most preferably are pyromellitic acid anhydride, 3,3′,4,4′-diphenylsulfonetetracarboxylic acid dianhydride, 3,3′,4,4′-diphenyl ether tetracarboxylic acid dianhydride and the like.

Two or more of these tetracarboxylic acid dianhydrides may be used in combination. One of preferable aspects is a combination use of pyromellitic acid anhydride and another tetracarboxylic acid dianhydride described above.

The diamine compound to be used in production of polyimide resin (a) is not limited as long as it has at least two amino groups in a molecule. A diamine compound having a phenolic hydroxy group is one of preferable diamine compounds.

For specific examples of the diamine compound, for example, examples of diamines not having a phenolic hydroxy group include m-phenylenediamine, p-phenylenediamine, m-tolylenediamine, 4,4′-diaminodiphenyl ether, 3,3′-dimethyl-4,4′-diaminodiphenyl ether, 3,4′-diaminodiphenyl ether, 4,4′-diaminodiphenyl thioether, 3,3′-dimethyl-4,4′-diaminodiphenyl thioether, 3,3′-diethoxy-4,4′-diaminodiphenyl thioether, 3,3′-diaminodiphenyl thioether, 4,4′-diaminobenzophenone, 3,3′-dimethyl-4,4′-diaminobenzophenone, 3,3′-diaminodiphenylmethane, 4,4′-diaminodiphenylmethane, 3,4′-diaminodiphenylmethane, 3,3′-dimethoxy-4,4′-diaminodiphenyl thioether, 2,2′-bis(3-aminophenyl)propane, 2,2′-bis(4-aminophenyl)propane, 4,4′-diaminodiphenyl sulfoxide, 3,3′-diaminodiphenylsulfone, 4,4′-diaminodiphenylsulfone, benzidine, 3,3′-dimethylbenzidine, 3,3′-dimethoxybenzidine, 3,3′-diaminobiphenyl, p-xylylenediamine, m-xylylenediamine, o-xylylenediamine, 2,2′-bis(3-aminophenoxyphenyl)propane, 2,2′-bis(4-aminophenoxyphenyl)propane, 1,3-bis(4-aminophenoxyphenyl)benzene, 1,3′-bis(3-aminophenoxyphenyl)propane, bis(4-amino-3-methylphenyl)methane, bis(4-amino-3,5-dimethylphenyl)methane, bis(4-amino-3-ethylphenyl)methane, bis(4-amino-3,5-diethylphenyl)methane, bis(4-amino-3-propylphenyl)methane, bis(4-amino-3,5-dipropylphenyl)methane, silicone diamine, isophoronediamine, hexamethylenediamine, trimethylhexamethylenediamine and the like; and examples of diamine compounds having a phenolic hydroxy group include 3,3′-diamino-4,4′-dihydroxydiphenylsulfone, 3,3′-diamino-4,4′-dihydroxydiphenyl ether, 3,3′-diamino-4,4′-dihydroxybiphenyl, 3,3′-dihydroxy-4,4′-diaminobiphenyl, 2,2-bis(3-amino-4-hydroxyphenyl)propane, 1,3-hexafluoro-2,2-bis(3-amino-4-hydroxyphenyl)propane, 9,9′-bis(3-amino-4-hydroxyphenyl)fluorene or the like. Preferable diamine compounds both having a phenolic hydroxy group and not having a phenolic hydroxy group include diaminodiphenyl compounds, silicone diamines or the like where two aminophenyl groups are bonded directly or through a cross-linking group. The cross-linking group in a diaminodiphenyl compound bonded through the cross-linking group includes an oxygen atom, a sulfur atom, —CO—, —SO₂—, —(CF₃)C(CF₃)—, C1 to C3 alkylene and the like, and more preferable is an oxygen atom. In addition, said diamine compound may have a substituent such as a C1 to C3 alkyl group or a C1 to C3 alkoxy group on the aminophenyl group.

These diamine compounds may be used alone or as a mixture of two or more kinds thereof. An aspect of preferable combination uses is a combination use of a diamine compound not having a phenolic hydroxy group and a diamine compound having a phenolic hydroxy group.

The polyimide compound (a) having a phenolic hydroxy group to be used in the present invention can be obtained using a tetracarboxylic acid dianhydride having a phenolic hydroxy group, too, however typically can be obtained using a diamine having a phenolic hydroxy group as described above. More preferably is a polyimide (a) obtained using a diamine having a phenolic hydroxy group. In the case of using the both in combination, the ratio of the both is not particularly limited, but typically in the mole ratio, a diamine having a phenolic hydroxy group is 0.1 to 10 mol, preferably 0.5 to 5 mol, further preferably 0.8 to 3 mol, and the most preferably 1 to 2 mol per mole of a diamine compound not having a phenolic hydroxy group.

The polyimide compound (a) to be used in the present invention is more preferably obtained from a combination of one or more of the above preferable tetracarboxylic acid dianhydride(s) and one or more of the above preferable diamine compound(s), and further preferably obtained from a combination of one or more of the more preferable tetracarboxylic acid dianhydride(s) and one or more of the preferable diamine compound(s), or of one or more of the more preferable tetracarboxylic acid dianhydride(s) and one or more of the more preferable diamine compound(s).

For example, preferable examples as the polyimide compound (a) include polyimide compounds obtained by using, as the tetracarboxylic acid dianhydride, an aromatic tetracarboxylic acid dianhydride, preferably having 1 to 2 benzene rings; or, it having two anhydride groups on the benzene ring if it has a benzene ring, or if it has two benzene rings, it having the two benzene rings having an acid anhydride group are bonded directly or through a cross-linking group (—O—, —CO— or —SO₂— as a cross-linking group) or as a condensed ring; more preferably pyromellitic acid anhydride, 3,3′,4,4′-diphenylsulfone tetracarboxylic acid dianhydride, 3,3′,4,4′-benzophenontetracarboxylic acid dianhydride, 3,3′,4,4′-biphenyl tetracarboxylic acid dianhydride or 3,3′,4,4′-diphenyl ether tetracarboxylic acid dianhydride and most preferably pyromellitic acid anhydride, 3,3′,4,4′-diphenylsulfone tetracarboxylic acid dianhydride, 3,3′,4,4′-diphenyl ether tetracarboxylic acid dianhydride; and as the diamine compound, a diaminodiphenyl compound where two aminophenyl groups are bonded directly or through a cross-linking group (the cross-linking group includes an oxygen atom, a sulfur atom, —CO—, —SO₂—, —(CF₃)C(CF₃)—, C1 to C3 alkylene or the like, and preferable is an oxygen atom) or a silicone diamine; more preferably, the polyimide compound obtained by using a diaminodiphenyl compound having a phenolic hydroxy group in combination as one of the diamine compounds, particularly for silicone diamine, the polyimide compound obtained by using a diaminodiphenyl compound having a phenolic hydroxy group in combination is preferable.

In the case of use as a negative-type, a diamine compound having a phenolic hydroxy group may inhibit polymerization of unsaturated double bond, and therefore a diamine compound having a phenolic hydroxy group where the hydroxy group is hindered by a substituent such as alkyl group, preferably C1 to C3 alkyl group and halogeno group at a position adjacent to the phenolic hydroxy group (the ortho position) is preferably used or the use amount is preferably decreased. The use amount of a diamine compound having a phenolic hydroxy group is 0 to 50 mol %, more preferably 0 to 30 mol % in the diamine compound. When used as a positive-type, as use of said diamine compound improves an alkali developability, increase of the use amount is preferable. The use amount of the diamine compound having a phenolic hydroxy group is 5 to 100 mol %, more preferably 10 to 80 mol % in the diamine compound. In addition, optionally, 50 to 85 mol % is more preferable.

The alkali-soluble polyimide resin (A) of the present invention preferably has a phenolic hydroxy group, and said phenolic hydroxy group is more preferably from a phenolic hydroxy group of the polyimide resin (a) to be used for synthesis of said resin (A). The polyimide resin (a) preferably has a molecular weight of 500 to 100,000 and more preferably 800 to 50,000. If the molecular weight is out of this range, the developability, photosensitivity, flexibility and heat resistance may be decreased.

In the present invention, the polyimide resin (a) can be obtained by carrying out the above condensation polymerization reaction in the presence of a lactone and a base as catalysts. This production method is preferable because aromatic polyimide copolymers having a straight chain can be easily produced without a side reaction.

The above lactone as a catalyst includes β-propiolactone, γ-butyrolactone, γ-valerolactone, δ-valerolactone, ε-caprolactone and the like, and preferable is γ-valerolactone. The base is preferably pyridine, 4-dimethylaminopyridine, 4-diethylaminopyridine or N-methylmorpholine.

The solvent to be used in synthesis of polyimide resin (a) includes methyl ethyl ketone, methyl propyl ketone, methyl isopropyl ketone, methyl butyl ketone, methyl isobutyl ketone, methyl n-hexyl ketone, diethyl ketone, diisopropyl ketone, diisobutyl ketone, cyclopentanone, cyclohexanone, methylcyclohexanone, acetylacetone, γ-butyrolactone, diacetone alcohol, cyclohexen-1-one, dipropyl ether, diisopropyl ether, dibutyl ether, tetrahydrofuran, tetrahydropyrane, ethyl isoamyl ether, ethyl-t-butyl ether, ethyl benzyl ether, cresyl methyl ether, anisole, phenetole, methyl acetate, ethyl acetate, propyl acetate, isopropyl acetate, butyl acetate, isobutyl acetate, amyl acetate, isoamyl acetate, acetic acid 2-ethylhexyl, cyclohexyl acetate, methyl cyclohexyl acetate, benzyl acetate, methyl acetoacetate, ethyl acetoacetate, methyl propionate, ethyl propionate, butyl propionate, benzyl propionate, methyl butyrate, ethyl butyrate, isopropyl butyrate, butyl butyrate, isoamyl butyrate, methyl lactate, ethyl lactate, butyl lactate, ethyl isovalerate, isoamyl isovalerate, diethyl oxalate, dibutyl oxalate, methyl benzoate, ethyl benzoate, propyl benzoate, methyl salicylate, N-methylpyrrolidone, N,N-dimethylformamide, N,N-dimethylacetoamide, dimethylsulfoxide and the like, but not limited thereto. They may be used as a mixture of one or more kinds thereof. The solvent to be used in the present invention can preferably dissolve a polyimide resin (a) produced by reaction and such a solvent can include γ-butyrolactone.

Hereinafter, the method for producing the polyimide resin (a) will be more specifically explained.

Under an inert atmosphere of nitrogen or the like, a catalyst, a diamine ingredient and a tetracarboxylic acid dianhydride as described above, and if needed, a dehydrating agent for removing water generated in reaction are accordingly added to a solvent, and reacted under heating and stirring while distilling away water generated when imide rings are formed, to obtain a polyimide resin (a) solution. In this connection, the dehydrating agent includes toluene and the like. Typically the reaction temperature is preferably 120 to 230° C. The reaction time depends largely on the polymerization degree of the desired polyimide and the reaction temperature. The reaction is preferably continued until the typically desired polymerization degree of polyimide is obtained, the reaction is preferably continued under the conditions determined according to the desired polymerization degree until the best viscosity typically as the best polymerization degree is obtained and the reaction time is typically 1 to 20 hours. Typically, the obtained solution can be used in the next reaction as it is. In addition, the obtained solution can be also charged in a poor solvent such as methanol and hexane to separate the resulting copolymers, then, the copolymers are purified by reprecipitation for removing by-products, and a polyimide resin (a) can be obtained.

In the alkali-soluble polyimide resin (A) of the present invention, the energy ray-curing type aqueous alkaline solution-soluble resin (b) has a group reactive to the polyimide resin (a) only at terminals, and any resin can be used without any restriction as long as it has hydroxy groups, isocyanate groups or carboxy groups at terminals or it is an acid anhydride. The general method for producing the energy ray-curing type aqueous alkaline solution-soluble resin (b) includes the following (1), (2) and (3).

(1) A reaction product (c) of an epoxy compound having two epoxy groups with a monocarboxylic acid compound having an ethylenically unsaturated group is reacted with a tetracarboxylic acid dianhydride (d) for esterification. In this case, if (c) has an excess number of moles, terminal(s) thereof are hydroxy group(s); and if (d) has an excess number of moles, terminal(s) thereof are acid anhydride(s). In addition, if terminal(s) thereof are hydroxy groups and reacted with a dicarboxylic acid monoanhydride, terminals thereof are carboxy groups.
(2) A reaction product (c) of an epoxy compound having two epoxy groups and a monocarboxylic acid compound having an ethylenically unsaturated group is reacted with a monocarboxylic acid compound (e) having two hydroxy groups in a molecule and a diisocyanate compound (f). In this case, if the total mole number of (c)+(e) is excessive to (f), terminal(s) thereof are hydroxy group(s); on the other hand, the mole number of (f) is excessive to the total mole number of (c)+(e), terminal(s) thereof are isocyanate group(s).
(3) A reaction product (c) of an epoxy compound having two epoxy groups with a monocarboxylic acid compound having an ethylenically unsaturated group is reacted with a tetracarboxylic acid dianhydride (d), and then reacted with a dicarboxylic acid monoanhydride.

The epoxy compound having two epoxy groups includes, for example, phenyl diglycidyl ethers such as hydroquinone diglycidyl ether, catechol diglycidyl ether and resorcinol diglycidyl ether; bisphenol type epoxy compounds such as bisphenol A type epoxy resin, bisphenol F type epoxy resin, bisphenol S type epoxy resin, an epoxy compound of 2,2-bis(4-hydroxyphenyl)-1,1,1,3,3,3-hexafluoropropane; hydrogenated bisphenol type epoxy compounds such as hydrogenated bisphenol A type epoxy resin, hydrogenated bisphenol F type epoxy resin, hydrogenated bisphenol S-type epoxy resin and an epoxy compound of hydrogenated 2,2-bis(4-hydroxyphenyl)-1,1,1,3,3,3-hexafluoropropane; halogenated bisphenol type epoxy compounds such as brominated bisphenol A type epoxy resin and brominated bisphenol F type epoxy resin; alicyclic diglycidyl ether compounds such as cyclohexanedimethanol diglycidyl ether compound; aliphatic diglycidyl ether compounds such as 1,6-hexanediol diglycidyl ether, 1,4-butanediol diglycidyl ether and diethylene glycol diglycidyl ether; polysulfide type diglycidyl ether compounds such as polysulfide diglycidyl ether; biphenol-type epoxy resin; or the like.

Preferable epoxy compounds are bisphenol type epoxy resins which may be hydrogenated or halogenated, more preferable are bisphenol A type epoxy resins which may be hydrogenated or halogenated, and further preferable are bisphenol type epoxy resins which are not hydrogenated or halogenated (more preferable are bisphenol A type epoxy resins).

Commercial products of these epoxy compounds are exemplified as follows. In these trade names, Epikote, Epomic and Celloxide are all registered trademarks and only each first trade name is accompanied by the symbol for registered trademark “RTM” in superscription and the symbols for the rest are omitted.

The Commercial products include, for example, bisphenol A type epoxy resins such as Epikote® 828, Epikote 1001, Epikote 1002, Epikote 1003 or Epikote 1004 (which are all manufactured by Japan Epoxy Resins Co., Ltd.), Epomic® R-140, Epomic R-301 or Epomic R-304 (which are all manufactured by Mitsui Chemical, Inc.), DER-331, DER-332 or DER-324 (which are all manufactured by The Dow Chemical Company), EPICLON® 840 or EPICLON 850 (which are all manufactured by DIC Corporation), UVR-6410 (manufactured by Union Carbide Corporation) or YD-8125 (manufactured by Tohto Kasei Co., Ltd.); bisphenol F type epoxy resins such as UVR-6490 (manufactured by Union Carbide Corporation), YDF-2001, YDF-2004 or YDF-8170 (which are all manufactured by Tohto Kasei Co., Ltd.), EPICLON 830 or EPICLON 835 (which are all manufactured by DIC Corporation); hydrogenated bisphenol A type epoxy resins such as HBPA-DGE (manufactured by Maruzen Petrochemical Co., Ltd.) or RIKARESIN HBE-100 (manufactured by New Japan Chemical Co., Ltd.); brominated bisphenol A type epoxy resins such as DER-513, DER-514 or DER-542 (which are all manufactured by The Dow Chemical Company); alicyclic epoxy resins such as Celloxide® 2021 (manufactured by Daicel Chemical Industries Ltd), RIKARESIN DME-100 (New Japan Chemical Co., Ltd.) or EX-216 (manufactured by Nagase ChemteX Corporation); aliphatic diglycidyl ether compounds such as ED-503 (manufactured by ADEKA Corporation), RIKARESIN W-100 (which are all manufactured by New Japan Chemical Co., Ltd.), EX-212, EX-214 or EX-850 (which are all manufactured by Nagase ChemteX Corporation); polysulfide type diglycidyl ether compounds such as FLEP-50 or FLEP-60 (which are all manufactured by Toray Thiokol Co., Ltd.); and biphenol-type epoxy compounds such as YX-4000 (manufactured by Japan Epoxy Resins Co., Ltd.).

The monocarboxylic acid compounds having an ethylenically unsaturated group include, for example, reaction product of acrylic acids, crotonic acid, α-cyanocinnamic acid, cinnamic acid, or, saturated or unsaturated dibasic acid with a monoglycidyl compound containing an unsaturated group. The acrylic acids include, for example, (meth)acrylic acid (which represents acrylic acid or/and methacrylic acid; and (meth)acrylate and the like represent the same), β-styrylacrylic acid, β-furfurylacrylic acid, or half esters as equimolar reaction product of saturated or unsaturated dibasic acid anhydride with a (meth)acrylate derivative having a hydroxy group in a molecule; half esters as equimolar reaction product of saturated or unsaturated dibasic acid with monoglycidyl(meth)acrylate derivative; and the like. In terms of sensitivity in the case of photosensitive resin compositions, preferable is (meth)acrylic acid, reaction product of (meth)acrylic acid with ε-caprolactone; or cinnamic acid, and more preferable is (meth)acrylic acid.

Accordingly, the reaction product (c) of an epoxy compound having two epoxy groups with a monocarboxylic acid compound having an ethylenically unsaturated group is preferably an epoxy (meth)acrylate and more preferably reaction product (c) obtained by reacting between preferable ones. More specifically, it is more preferable to use a (meth)acrylic acid as said monocarboxylic acid compound and a bisphenol type epoxy compound, further preferably a bisphenol A type epoxy compound as said epoxy compound.

As the tetracarboxylic acid dianhydride (d), the above compounds to be used in production of polyimide resin (a) can be used. The tetracarboxylic acid dianhydride (d) is preferably pyromellitic acid anhydride.

Accordingly, the resin (b) obtained by reacting the reaction product (c) described above with the tetracarboxylic acid dianhydride (d) is preferably a resin obtained by reacting an epoxy(meth)acrylate with the tetracarboxylic acid dianhydride (d), more preferably a resin using a bisphenol type epoxy compound as the above epoxy compound, and further preferably a resin using a bisphenol A type epoxy compound. In the above, it is further preferable to use pyromellitic acid anhydride as the tetracarboxylic acid dianhydride (d) and a resin by reacting an epoxy(meth)acrylate with pyromellitic acid anhydride is one of more preferable resins.

As the monocarboxylic acid compound (e) having two hydroxy groups in a molecule, any diol compound can be used as long as it has a alcoholic hydroxy group or a phenolic hydroxy group together with a carboxy group in a molecule; preferable is dimethylol propionic acid or dimethylol butanoic acid and more preferable is dimethylol propionic acid.

As the diisocyanate compound (f), any diisocyanate compound can be used as long as it has two isocyanate groups in a molecule, and plural diisocyanate compounds can be simultaneously reacted. The diisocyanate compound (f) includes, for example, phenylene diisocyanate, tolylene diisocyanate, xylylene diisocyanate, tetramethylxylylene diisocyanate, diphenylmethane diisocyanate, naphthalene diisocyanate, tolidene diisocyanate, hexamethylene diisocyanate, dicyclohexylmethane diisocyanate, isophorone diisocyanate, arylene sulfone ether diisocyanate, allylcyan diisocyanate, N-acyl diisocyanate, trimethylhexamethylene diisocyanate, 1,3-bis(isocyanatemethyl)cyclohexane, norbornane-diisocyanate or the like. Among them, preferable compounds include isophorone diisocyanate, diphenylmethane diisocyanate, hexamethylene diisocyanate and trimethylhexamethylene diisocyanate, and isophorone diisocyanate is one of more preferable compounds.

Accordingly, the resin (b) obtained by reacting the above reaction product (c) with a monocarboxylic acid compound (e) having two hydroxy groups in a molecule and a diisocyanate compound (f) is preferably obtained by using dimethylol propionic acid or dimethylol butanoic acid as said monocarboxylic acid compound (e), more preferably dimethylol propionic acid; or by using, as the diisocyanate compound (f), the preferable compound mentioned above, particularly isophorone diisocyanate; more preferably by using the both. In addition, these and the preferable compound as the above reaction product (c) can be used in combination to obtain further preferable resin (b). Such resin (b) is obtained by reacting, for example, an epoxy(meth)acrylate with dimethylol propionic acid or dimethylol butanoic acid (more preferably dimethylol propionic acid) and an diisocyanate compound (f), and for said resin (b) it is also more preferable to use isophorone diisocyanate as the diisocyanate compound (f).

The resin (b) obtained by reacting the above reaction product (c) with a tetracarboxylic acid dianhydride (d) and then further reacting with a dicarboxylic acid monoanhydride can include resin (b-4) terminated with carboxy groups. Said resin (b-4) can be obtained in that a more than equimolar amount of the above reaction product (c) to the tetracarboxylic acid dianhydride (d) is used to give a resin (b-1) terminated with hydroxy groups and said resin (b-1) is reacted with a dicarboxylic acid monoanhydride.

The dicarboxylic acid monoanhydride includes, for example, monoanhydrides of straight chain aliphatic dicarboxylic acids such as maleic anhydride, succinic anhydride or itaconic acid anhydride; or phthalic monoanhydrides such as phthalic anhydride, tetrahydrophthalic anhydride, hexahydrophthalic anhydride, methylendomethylenetetrahydrophthalic anhydride or methyltetrahydrophthalic anhydride, preferably phthalic monoanhydride and more preferably tetrahydrophthalic anhydride.

Accordingly, the resin (b) obtained by reacting a dicarboxylic acid monoanhydride is preferably a resin obtained by using a phthalic acid-based monoanhydride as the dicarboxylic acid monoanhydride, more preferably a resin obtained by using a tetrahydrophthalic anhydride.

In addition, similarly to the other resins described above as the resin (b), preferable is a combination of the preferable reaction product described above as the reaction product (c) and said dicarboxylic acid monoanhydride(s). Furthermore, further preferable is a combination with the preferable tetracarboxylic acid dianhydride (d) mentioned above.

For example, a resin obtained by using the above epoxy(meth)acrylate as the above reaction product (c) and a phthalic monoanhydride as the dicarboxylic acid monoanhydride, more preferably a tetrahydrophthalic anhydride is one of preferable resins as the resin (b), and a resin obtained by using pyromellitic acid as the tetracarboxylic acid dianhydride in addition to the combination is further preferable as the resin (b).

These reactions can be carried out without a solvent or in an organic solvent; or in a sole solvent such as cross-linking agent (C) described later or in a mixture of organic solvents.

The organic solvent includes, for example, amides such as N-methylpyrrolidone, dimethylacetoamide and dimethylformamide; ketones such as acetone, ethylmethyl ketone and cyclohexanone; aromatic carbon hydrides such as benzene, toluene, xylene and tetramethylbenzene; glycol ethers such as ethylene glycol dimethyl ether, ethylene glycol diethyl ether, dipropylene glycol monomethyl ether, dipropylene glycol dimethyl ether, dipropylene glycol diethyl ether, triethylene glycol dimethyl ether and triethylene glycol diethyl ether; esters such as ethyl acetate, butyl acetate, methyl cellosolve acetate, ethyl cellosolve acetate, butyl cellosolve acetate, carbitol acetate, propylene glycol monomethyl ether acetate, glutaric acid dialkyl, succinic acid dialkyl and adipic acid dialkyl; cyclic esters such as γ-butyrolactone; petroleum solvents such as petroleum ether, petroleum naphtha, hydrogenated petroleum naphtha and solvent naphtha; and the like.

The reaction of an epoxy compound having two epoxy groups with a monocarboxylic acid compound having an ethylenically unsaturated group can be carried out without a solvent. The preferable ratio of said epoxy compound and said monocarboxylic acid compound to be charged is 0.8 to 1.2 equivalents, more preferably 0.9 to 1.1 equivalents and most preferably about 1 equivalent of said monocarboxylic acid compound, per 1 equivalent of epoxy group of epoxy compound having two epoxy groups. When the ratio of said monocarboxylic acid compound to be charged is out of the range from 0.8 to 1.2 equivalents, gelation may occur during reaction and the alkali-soluble polyimide resin (A) finally obtained may have lower heat stability.

A heat polymerization inhibitor is preferably added in the reaction of an epoxy compound having two epoxy groups with a monocarboxylic acid compound having an ethylenically unsaturated group in order to control the heat polymerization reaction. The use amount of heat polymerization inhibitor is 0.05 to 10% by weight and more preferably 0.1 to 5% by weight to the reaction product. Said heat polymerization inhibitor includes hydroquinones, 2-methylhydroquinone, hydroquinone monomethyl ether, 2,6-ditertiary butyl-p-cresol and the like.

In addition, a catalyst is preferably used to promote the reaction of said epoxy compound with said monocarboxylic acid compound. The use amount of said catalyst is 0.1 to 10% by weight and preferably 0.2 to 5% by weight to the reaction product. In said reaction, the reaction temperature is 60 to 150° C. and preferably 80 to 130° C. and the reaction time is 3 to 60 hours and preferably 5 to 40 hours. Catalysts to be used in this reaction include, for example, dimethylaminopyridine, triethylamine, benzyldimethylamine, triethylammonium chloride, benzyltrimethylammonium bromide, benzyltrimethylammonium iodide, triphenyl phosphine, triphenylstibine, methyltriphenylstibine, chrome 2-ethylhexanate, chrome octanoate, zinc 2-ethylhexanate, zinc octanoate, octanoic acid zirconium, dimethyl sulfide, diphenyl sulfide and the like.

As described above, one of the above resin (b) to be used in the present invention can be obtained by reacting the reaction product (c) obtained in the above reaction of an epoxy compound having two epoxy groups and a monocarboxylic acid compound having an ethylenically unsaturated group with a tetracarboxylic acid dianhydride (d), and in addition, the obtained reaction product is further reacted with a dicarboxylic acid monoanhydride to give another resin (b). These reactions are all esterification reactions, the reaction temperature is 70 to 150° C. and preferably 80 to 120° C., and the reaction time is 1 to 24 hours and preferably 3 to 15 hours. The reactions can be basically carried out without a catalyst, but a catalyst can be used to promote the reactions and the use amount of said catalyst is 10% by weight or less to the total amount of the material compound.

The reaction of the above reaction product (c) with a monocarboxylic acid compound (e) having two hydroxy groups in a molecule and a diisocyanate compound (f) in order to obtain the above resin (b) is typically carried out in the above solvent, the reaction temperature is 30 to 150° C. and preferably 40 to 120° C., and the reaction time is 2 to 24 hours and preferably 5 to 18 hours. The reaction can be basically carried out without a catalyst; however, a catalyst such as dibutyltin dilaurylate is preferably used in order to promote the reaction. The use amount of said catalyst is 10% by weight or less to the reactants. In this regard, such a solvent or a heat polymerization inhibitor as described above may be used in this case. This reaction is monitored in absorption near 2270 cm⁻¹ in infrared absorption spectrum and the isocyanate value of samples while sampling is carried out appropriately. That is, the reaction is preferably stopped when this absorption or the isocyanate value is not observed.

The polyimide resin (A) of the present invention is obtained by reaction of the above polyimide resin (a) with the above resin (b), and a preferable polyimide resin (A) is obtained from a combination of the above preferable polyimide resin (a) with the above resin (b), preferably the above preferable resin (b).

A preferable alkali-soluble polyimide resin (A) is obtained in that, for example, an aromatic tetracarboxylic acid dianhydride and a diaminodiphenyl compound (the cross-linking group can include an oxygen atom, a sulfur atom, —CO—, —SO₂—, —(CF₃)C(CF₃)—, C1 to C3 alkylene or the like, and preferable is an oxygen atom) or a silicone diamine are used to obtain a polyimide compound (a) (as one of diamine compounds, more preferable is a polyimide compound (a) where a diaminodiphenyl compound having a phenolic hydroxy group is used in combination, particularly a diaminodiphenyl compound having a phenolic hydroxy group in the case of silicone diamine), which is then reacted with the above resin (b), preferably a resin (b) obtained by reacting an epoxy(meth)acrylate (the above reaction product (c)) with (i) a tetracarboxylic acid dianhydride (d) or with (ii) a monocarboxylic acid compound (e) having two hydroxy groups in a molecule and a diisocyanate compound (f), or a resin (b) obtained by reacting an epoxy(meth)acrylate (the above reaction product (c)) with (iii) a tetracarboxylic acid dianhydride (d) and then a dicarboxylic acid anhydride. In this regard, it is more preferable that, for example, (i) pyromellitic dianhydride is used as the tetracarboxylic acid dianhydride (d); or (ii) dimethylol propionic acid or dimethylol butanoic acid (more preferably dimethylol propionic acid) is used as the monocarboxylic acid compound (e) having two hydroxy groups in a molecule, or isophorone diisocyanate is used as the diisocyanate compound (f); or (iii) phthalic anhydride-based monoanhydride is used as the dicarboxylic acid anhydride. It is further preferable to combine 2 to 4 among them.

In addition, in the alkali-soluble polyimide resin (A) of the present invention, the energy ray-curing type aqueous alkaline solution-soluble resin (b) has preferably an ethylenically unsaturated group equivalent of 300 to 2000 g/equivalent.

Further, the solid acid value of the polyimide resin (A) of the present invention is preferably about 5 to 200 mg·KOH/g. When out of this range, developability, photosensitivity, flexibility and heat resistance may decrease.

The polyimide resin (A) of the present invention can be separated from a reaction solution and then dissolved again to be used as a solution, but the reaction solution obtained is preferably used as it is. A resin solution (composition) containing the polyimide resin (A) of the present invention and a solvent can be used as a photosensitive, aqueous alkaline solution-soluble polyimide resin composition by mixing a photopolymerization initiator or a photoacid-generating agent. The content of said polyimide resin in the resin solution containing the polyimide resin (A) of the present invention and a solvent is not particularly limited, but typically 10 to 80% by weight and more preferably about 15 to 70% to the whole of said resin solution.

In the case where the reaction of the polyimide resin (a) with the above resin (b) is esterification, the reaction temperature is 70 to 150° C. and preferably 80 to 120° C. and the reaction time is 1 to 24 hours and preferably 3 to 15 hours. The reaction can be basically carried out without a catalyst, but a catalyst can be used to promote the reaction. The use amount of said catalyst is 10% by weight or less to the total amount of the polyimide resin (a) and the above resin (b).

In the case where the reaction of the polyimide resin (a) with the above resin (b) is imidization, the reaction temperature is 100 to 180° C. and preferably 120 to 150° C. and the reaction time is 1 to 24 hours and preferably 3 to 15 hours. The reaction can be basically carried out without a catalyst.

In the case that the reaction of the polyimide resin (a) with the above resin (b) is polymerization by formation of amic acid, the reaction temperature is 30 to 100° C. and preferably 40 to 80° C. and the reaction time is 1 to 24 hours and preferably 3 to 15 hours. The reaction can be basically carried out without a catalyst.

In the case where the reaction of the polyimide resin (a) with the above resin (b) is polymerization by formation of urea bond, the reaction temperature is 70 to 150° C. and preferably 80 to 120° C. and the reaction time is 1 to 24 hours and preferably 3 to 15 hours. The reaction can be basically carried out without a catalyst, but a catalyst such as triphenyl phosphite to promote the reaction can be used and the use amount of said catalyst is 10% by weight or less to the total amount of the polyimide resin (a) and the above resin (b).

In the case where the reaction of the polyimide resin (a) with the above resin (b) is polymerization by formation of amide bond, the reaction temperature is 70 to 150° C. and preferably 80 to 120° C. and the reaction time is 1 to 24 hours and preferably 3 to 15 hours. The reaction can be basically carried out without a catalyst, but a catalyst can be used and the use amount of said catalyst is 10% by weight or less to the total amount of polyimide resin (a) and the above resin (b).

The alkali-soluble polyimide resin (A) of the present invention preferably has, when used as a negative-type, an ethylenically unsaturated group equivalent of 300 to 2000 g/equivalent and more preferably 350 to 1,500 g/equivalent. If this equivalent is 300 g/equivalent or less, the crosslink density is too high, whereby at worst cracking may occur in cured products, resulting in peeling from the substrate. On the other hand, if it is unpreferably 2,000 g/equivalent or more, photosensitivity may be too low. In addition, it is preferably 1,000 g/equivalent or more when used as a positive-type. Its upper limit is not imposed, but it is typically 5,000 g/equivalent or less and more preferably 4,000 g/equivalent or less.

The alkali-soluble polyimide resin (A) of the present invention is preferably added in order that the solid acid value becomes to 5 to 200 mg·KOH/g. If the solid acid value is less than 5 mg·KOH/g, solubility to aqueous alkaline solutions is insufficient, whereby the resin may remain as residue in patterning or at worst patterning may not be performed. On the other hand, if the solid acid value is unpreferably more than 200 mg·KOH/g, solubility to aqueous alkaline solutions is too high, whereby pattern may detached.

The alkali-soluble polyimide resin (A) of the present invention preferably has a weight average molecular weight of 10,000 to 400,000 as polystyrene. If the molecular weight is less than 10,000, physical properties of coated film after patterning, particularly flexibility, heat resistance, plating resistance and the like are deteriorated. On the other hand, if the molecular weight is more than 400,000, solubility to aqueous alkaline solutions is insufficient, whereby the resin may remain as residue in patterning or at worst patterning may not be performed. The weight average molecular weight is more preferably 20,000 to 100,000 and further preferably 25,000 to 80,000 as polystyrene.

The alkali-soluble polyimide resin (A) of the present invention thus obtained can be, if a solvent is used therein, isolated by removing the solvent in an appropriate manner, but it can be often used without removing the solvent when used as a photosensitive resin composition.

The alkali-soluble polyimide resin (A) of the present invention is typically soluble in aqueous alkaline solutions and also in the above solvents, whereby it can be developed with a solvent when used for cover lays, solder resists, plating resists and the like.

The photosensitive resin composition of the present invention is, when used as a negative-type, characterized by containing an alkali-soluble polyimide resin (A), a photopolymerization initiator (B), a cross-linking agent (C) as an optional component and further a curing agent (D) as an optional component.

The content ratio of the alkali-soluble polyimide resin (A) used in the photosensitive resin composition of the present invention is, when the solid content of the photosensitive resin composition is 100% by weight, typically 15 to 70% by weight (hereinafter, % represents % by weight unless otherwise specified) and preferably 20 to 60%.

In this connection, the solid content in the photosensitive resin composition of the present invention is about 20 to 80% and preferably about 30 to 75% to the whole photosensitive resin composition and the rest is solvent.

Specific examples of the photopolymerization initiator (B) to be used in the photosensitive resin composition of the present invention include, for example, benzoins such as benzoin, benzoinmethyl ether, benzomethyl ether, benzoinpropyl ether and benzoinisobutyl ether; acetophenones such as acetophenone, 2,2-diethoxy-2-phenylacetophenone, 1,1-dichloroacetophenone, 2-hydroxy-2-methyl-phenylpropan-1-one, diethoxyacetophenone, 1-hydroxycyclohexylphenyl ketone and 2-methyl-1-[4-(methylthio)phenyl]-2-morpholinopropan-1-one; anthraquinones such as 2-ethylanthraquinone, 2-tertiarybutylanthraquinone, 2-chloroanthraquinone and 2-amylanthraquinone; thioxanthones such as 2,4-diethylthioxanthone, 2-isopropylthioxanthone and 2-chlorothioxanthone; ketals such as acetophenone dimethyl ketal and benzyl dimethyl ketal; benzophenones such as benzophenone, 4-benzoyl-4′-methyldiphenylsulfide and 4,4′-bismethylaminobenzophenone; phosphineoxides such as 2,4,6-trimethylbenzoyidiphenylphosphineoxide and bis(2,4,6-trimethylbenzoyl)-phenylphosphineoxide; and the like. The ratio of these to be added is, when the solid content of the photosensitive resin composition is 100%, typically 1 to 30%, preferably 2 to 25% and more preferably about 2 to 15%.

These can be used alone or as a mixture of two or more kinds thereof, and it can be also used in combination of an accelerator, for example, tertiary amines such as triethanolamine and methyldiethanolamine, benzoic acid derivatives such as N,N-dimethylaminobenzoic acid ethyl ester and N,N-dimethylaminobenzoic acid isoamyl ester; and the like. The addition amount of these accelerators is preferably 100% or less to the photopolymerization initiator (B).

Specific examples of the cross-linking agent (C) to be used in the photosensitive resin composition of the present invention includes, for example, 2-hydroxyethyl(meth)acrylate, 2-hydroxypropyl(meth)acrylate, 1,4-butanediol mono(meth)acrylate, carbitol(meth)acrylate, acryloylmorpholine, half ester as a reaction product of a hydroxy group-containing (meth)acrylate (for example, 2-hydroxyethyl(meth)acrylate, 2-hydroxypropyl(meth)acrylate, 1,4-butanediol mono(meth)acrylate and the like) with an acid anhydride of a polycarboxylic acid compound (for example, succinic anhydride, maleic anhydride, phthalic anhydride, tetrahydrophthalic anhydride, hexahydrophthalic anhydride and the like), polyethylene glycol di(meth)acrylate, tripropylene glycol di(meth)acrylate, trimethylolpropane tri(meth)acrylate, trimethylolpropane polyethoxy tri(meth)acrylate, glycerine polypropoxy tri(meth)acrylate, di(meth)acrylate of ε-caprolactone adduct of neopentyl glycol hydroxypivalate (for example, KAYARAD® HX-220 and HX-620 manufactured by Nippon Kayaku Co., Ltd. and the like), pentaerythritol tetra(meth)acrylate, poly(meth)acrylate of a reactant of dipentaerythritol with ε-caprolactone, dipentaerythritol poly(meth)acrylate, epoxy(meth)acrylate as a reaction product of mono- or poly-glycidyl compound (for example, butyl glycidyl ether, phenyl glycidyl ether, polyethylene glycol diglycidyl ether, polypropylene glycol diglycidyl ether, 1,6-hexanediol diglycidyl ether, hexahydrophthalic acid diglycidyl ester, glycerine polyglycidyl ether, glycerine polyethoxy glycidyl ether, trimethylolpropane polyglycidyl ether, trimethylolpropane polyethoxy polyglycidyl ether and the like) with (meth)acrylic acid, and the like. The ratio of these to be added is, when the solid content of the photosensitive resin composition is 100%, typically 0 to 40%, preferably 2 to 40%, more preferably 5 to 30% and optionally, preferably about 0 to 10%.

The curing agent (D) as an optional component to be used in the photosensitive resin composition of the present invention includes, for example, an epoxy compound, an oxazine compound and the like. Typically, it is preferably a polyfunctional epoxy resin. The curing agent (D) is reacted, by heating, with carboxy groups remaining in a resin-coated film after photo-curing and is used in order to obtain a cured coated film having higher chemical resistance.

Specific examples of the epoxy compound to be used as the curing agent (D) includes, for example, phenolic novolak-type epoxy resin, cresol novolak-type epoxy resin, trishydroxyphenylmethane-type epoxy resin, dicyclopentadienephenol-type epoxy resin, bisphenol A type epoxy resin, bisphenol F type epoxy resin, biphenol-type epoxy resin, bisphenol A novolak-type epoxy resin, naphthalene skeleton-containing epoxy resin, heterocyclic epoxy resin, glyoxal type epoxy resin and the like. Among them, more preferable is a biphenol-type epoxy resin.

The phenolic novolak-type epoxy resin includes, for example, EPICLON N-770 (manufactured by DIC Corporation), D.E.N 438 (manufactured by The Dow Chemical Company), Epikote 154 (manufactured by Japan Epoxy Resins Co., Ltd.), RE-306 (manufactured by Nippon Kayaku Co., Ltd.) and the like. The cresol novolak-type epoxy resin includes, for example, EPICLON N-695 (manufactured by DIC Corporation), EOCN-102S, EOCN-103S and EOCN-104S (manufactured by Nippon Kayaku Co., Ltd.), UVR-6650 (manufactured by Union Carbide Corporation), ESCN-195 (manufactured by Sumitomo chemical Co., Ltd.) and the like.

The trishydroxyphenylmethane-type epoxy resin includes, for example, EPPN-503, EPPN-502H and EPPN-501H (manufactured by Nippon Kayaku Co., Ltd.), TACTIX-742 (manufactured by The Dow Chemical Company), Epikote E1032H60 (manufactured by Japan Epoxy Resins Co., Ltd.) and the like. The dicyclopentadienephenol-type epoxy resin includes, for example, EPICLON EXA-7200 (manufactured by DIC Corporation), TACTIX-556 (manufactured by The Dow Chemical Company) and the like.

The bisphenol type epoxy resin includes, for example, bisphenol A type epoxy resins such as Epikote 828, Epikote 1001 (manufactured by Japan Epoxy Resins Co., Ltd.), UVR-6410 (manufactured by Union Carbide Corporation), D.E.R-331 (manufactured by The Dow Chemical Company) and YD-8125 (manufactured by Tohto Kasei Co., Ltd.); bisphenol F type epoxy resins such as UVR-6490 (manufactured by Union Carbide Corporation), YDF-8170 (manufactured by Tohto Kasei Co., Ltd.) and LCE-21 (manufactured by Nippon Kayaku Co., Ltd.); and the like.

The biphenol-type epoxy resin includes, for example, biphenol-type epoxy resins such as NC-3000, NC-3000H (manufactured by Nippon Kayaku Co., Ltd.); bixylenol type epoxy resin such as YX-4000 (manufactured by Japan Epoxy Resins Co., Ltd.); YL-6121 (manufactured by Japan Epoxy Resins Co., Ltd.); and the like. The bisphenol A novolak-type epoxy resin includes, for example, EPICLON N-880 (manufactured by DIC Corporation), Epikote E157S75 (manufactured by Japan Epoxy Resins Co., Ltd.) and the like.

The naphthalene skeleton-containing epoxy resin includes, for example, NC-7000 (manufactured by Nippon Kayaku Co., Ltd.), EXA-4750 (manufactured by DIC Corporation) and the like. The alicyclic epoxy resin includes, for example, EHPE-3150 (manufactured by Daicel Chemical Industries Ltd) and the like. The heterocyclic epoxy resin includes, for example, TEPIC (manufactured by Nissan Chemical Industries, Ltd.)

Specific examples of the oxazine compound to be used as the curing agent (D) includes, for example, B-m-type benzooxazine, P-a-type benzooxazine and B-a-type benzooxazine (all manufactured by Shikoku Chemicals Corporation).

Specific examples of the glyoxal type epoxy resin to be used as the curing agent (D) include, for example, GTR-1800 (manufactured by Nippon Kayaku Co., Ltd.).

As for the ratio of the curing agent (D) to be added, the curing agent has preferably an epoxy equivalent of 200% or less of the carboxyl equivalent calculated from the solid acid value and use amount of the alkali-soluble polyimide resin (A) of the present invention.

If this ratio is unpreferably more than 200%, developability of the photosensitive resin composition of the present invention may be significantly deteriorated. This ratio is, when the solid content of the photosensitive resin composition is 100%, typically about 0 to 50% and preferably about 0 to 40%.

In addition, a variety of additives can be added if needed for the purpose of improving various performances of the composition; for example, fillers such as talc, barium sulfate, calcium carbonate, magnesium carbonate, barium titanate, aluminum hydroxide, aluminum oxide, silica and clay; a thixotropy imparting agents such as aerosil; colorants such as phthalocyanine blue, phthalocyanine green and titanium oxide; silicone- or fluorine-type leveling agents or antifoaming agents; heat polymerization inhibitors such as hydroquinones and hydroquinone monomethyl ether; and the like.

In this regard, the above curing agent (D) may be mixed in the above resin composition in advance, or may be used by being mixed before coating on printed wiring boards. That is, it is preferred that two types of solutions of a main agent solution where the above (A) ingredient as a main body is mixed with an epoxy curing accelerator and the like and a curing agent solution which contains the curing agent (D) as a main body are prepared, and then these two solutions are mixed in use.

The photosensitive resin composition of the present invention is characterized by containing an alkali-soluble polyimide resin (A) and a photoacid-generating agent (E), when used as a positive-type.

The photoacid-generating agent (E) includes 1,2-benzoquinonediazide-4-sulfonic acid ester, 1,2-naphthoquinone-2-diazide-5-sulfonic acid ester, 1,2-naphthoquinone-2-diazide-4-sulfonic acid ester, 1,2-naphthoquinone-2-diazide-5-sulfonic acid ester-ortho cresol ester, 1,2-naphthoquinone-2-diazide-5-sulfonic acid ester-para cresol ester and the like. Esterification ingredients can include, for example, 2,4-dihydroxybenzophenon, 2,3,4-trihydroxybenzophenon, 2,3,4,4′-tetrahydroxybenzophenon, 2,2′,3,4,4′-pentahydroxybenzophenon, phenol, 1,3-dihydroxybenzene, 1,3,5-trihydroxybenzene, bisphenol A, bisphenol F, bisphenol S, novolak resins, methyl gallate, ethyl gallate, phenyl gallate and the like. The addition amount of the photoacid-generating agent (E) is about 5 to 40% and preferably about 7 to 30% to the alkali-soluble polyimide resin (A).

The photosensitive resin composition of the present invention can be used also as a dry film resist composed of a structure in which a resin composition is sandwiched between a support film and a protection film.

The photosensitive resin composition (liquid or film) of the present invention is useful as an insulating material between layers of electronic parts and a resist material such as solder resists and cover lays for optical waveguides connecting between optical components and printed substrates, and also can be used as a color filter, a printing ink, an alignment film, a sealer, a paint, a coating agent, an adhesive or the like.

The active energy rays described in the present invention includes ultraviolet rays, visible light rays, infrared rays, electron rays, radiation rays and the like. In curing the alkali-soluble polyimide resin (A) of the present invention, ultraviolet rays or electron rays are most preferably used in view of application. Cured products of the present invention can be cured in a conventional manner by irradiation of energy rays such as ultraviolet rays. For example, irradiation of ultraviolet rays can be carried out by using an ultraviolet ray generating apparatus such as a low pressure mercury lamp, a high pressure mercury lamp, an ultrahigh pressure mercury lamp, a xenon lamp and an ultraviolet ray-emitting laser (excimer laser and the like).

Cured products of the resin composition of the present invention can be utilized, for example, for electric and electronic parts such as resist film and insulating materials between layers for build-up methods. Specific examples of these include, for example, computers, household electric appliances, mobile devices and the like. The film thickness of cured product layers for these is about 0.5 to 160 μm and preferably about 1 to 100 μm.

The printed wiring board of the present invention can be obtained, for example, as follows. That is, when the resin composition to be used is a liquid, a substrate for printed wiring is coated with a composition of the present invention at a film thickness of 5 to 160 μm by a method such as a screen printing method, a spray method, a roll coating method, an electrostatic coating method and a curtain coating method and the resulting is dried at a temperature of typically 50 to 110° C. and preferably 60 to 100° C. to form a coated film. And then, the coated film is irradiated with high energy rays such as ultraviolet rays at a laser energy density of about 10 to 2000 mJ/cm², directly or indirectly via a photomask formed an exposure pattern such as a negative film, a positive film or the like, and developed by, for example, spray, oscillating immersion, blushing, scrubbing or the like, using the developer described later. And then, the resulting is, further if needed, irradiated with ultraviolet rays and heat-treated at a temperature of typically 100 to 250° C. and preferably 140 to 180° C. to obtain a printed wiring board having a permanent protective film excellent in gold plating properties and satisfying such properties as heat resistance, solvent resistance, acid resistance, adhesion properties and flexibility.

As the above aqueous alkaline solution to be used in development, an aqueous inorganic alkaline solution such as potassium hydroxide, sodium hydroxide, sodium carbonate, potassium carbonate, sodium hydrogen carbonate, potassium hydrogen carbonate, sodium phosphate or potassium phosphate and an aqueous organic alkaline solution such as tetramethyl ammonium hydroxide, tetraethyl ammonium hydroxide, tetrabutyl ammonium hydroxide, monoethanolamine, diethanolamine or triethanolamine can be used.

The resin, when used as a negative-type, having an acid value of 70 or more and a weight average molecular weight of 40,000 or less; and the resin, when used as a positive-type, having an acid value of 10 or more and a weight average molecular weight of 50,000 or less can be developed with dilute alkali such as 1% sodium carbonate, 1% sodium hydroxide and 1% tetramethyl ammonium hydroxide.

### EXAMPLE

Hereinafter, the present invention will be more specifically explained with reference to the following Examples, but not limited thereto.

### Synthesis Example 1

### Synthesis of Polyimide Resin (a-1)

In a 3 L flask equipped with a stirring device, a circulation tube, a water trap and a thermometer, which is purged with nitrogen gas, 1052.3 g of γ-butyrolactone as a solvent, 87.3 g of PMDA (pyromellitic acid anhydride manufactured by Degussa AG; molecular weight: 218.1), 279.2 g of ODPA (3,3′,4,4′-diphenyl ether tetracarboxylic acid dianhydride manufactured by MANAC Incorporated; molecular weight: 310.2), 200.2 g of 3,4′-diaminodiphenyl ether (manufactured by Mitsui Chemical, Inc.; molecular weight: 200.2), 13.0 g of γ-valerolactone and 20.6 g of pyridine as catalysts, and 20 g of toluene were charged and stirred at 180° C. for 8 hours while removing water generated by the reaction, the toluene as a dehydrating agent and the catalyst, to obtained a resin solution containing 35% polyimide resin (this solution is referred to as (a-1)). Weight average molecular weight: 17700.

### Synthesis Example 2

### Synthesis of Polyimide Resin (a-2)

In a 5 L flask equipped with a stirring device, a circulation tube, a water trap and a thermometer, which is purged with nitrogen gas, 1741.4 g of γ-butyrolactone as a solvent, 358.3 g of DSDA (3,3′,4,4′-diphenylsulfone tetracarboxylic acid dianhydride manufactured by New Japan Chemical Co., Ltd.; molecular weight: 358.28), 370.4 g of BY16-853U (silicone diamine manufactured by Toray Dow Corning Corporation; molecular weight: 926), 209.0 g of ADPE (3,3′-diamino-4,4′-dihydroxydiphenyl ether manufactured by Nippon Kayaku Co., Ltd.; molecular weight: 232.24), 10.0 g of γ-valerolactone and 15.8 g of pyridine as catalysts and 20 g of toluene were charged and stirred at 180° C. for 8 hours while removing water generated by the reaction, the toluene as a dehydrating agent and the catalysts, to obtained a resin solution containing 35% polyimide resin (this solution is referred to as (a-2)). Weight average molecular weight: 23200.

### Synthesis Example 3

### Synthesis (Esterification) of Energy Ray-Curable Aqueous Alkaline Solution-Soluble Resin (b-1a)

In a 5 L flask equipped with a stirring device, a circulation tube and a thermometer, 1104.0 g of RE310S (bifunctional bisphenol A type epoxy resin manufactured by Nippon Kayaku Co., Ltd.; epoxy equivalent: 184 g/equivalent) as a bisphenol A type epoxy compound, 432.3 g of acrylic acid (manufactured by Nippon Shokubai Co., Ltd.; molecular weight: 72.06), 4.62 g of 2,6-ditertiary butyl-p-cresol as a heat polymerization inhibitor and 4.62 g of triphenylphosphine as a reaction catalyst were charged and then reacted at a temperature of 98° C. until the acid value of the reaction solution was 0.5 mg·KOH/g or less, to obtain an epoxy carboxylate compound (theoretical molecular weight: 512.1).

In this reaction solution, 845.4 g of γ-butyrolactone as a reaction solvent and 436.2 g of PMDA (pyromellitic acid anhydride manufactured by Degussa AG; molecular weight: 218.1) were charged and reacted at 98° C. for 10 hours to obtain a resin solution containing 70% energy ray-curable aqueous alkaline solution-soluble resin (this solution is referred to as (b-1a) (terminal: hydroxy group)). The acid value was measured, resulting in 114 mg·KOH/g (solid acid value).

### Synthesis Example 4

### Synthesis (Esterification) of Energy Ray-Curable Aqueous Alkaline Solution-Soluble Resin (b-2)

In a 5 L flask equipped with a stirring device, a circulation tube and a thermometer, 736.0 g of RE310S (bifunctional bisphenol A type epoxy resin manufactured by Nippon Kayaku Co., Ltd.; epoxy equivalent: 184 g/equivalent) as a bisphenol A type epoxy compound, 288.24 g of acrylic acid (manufactured by Nippon Shokubai Co., Ltd.; molecular weight: 72.06), 3.07 g of 2,6-ditertiary butyl-p-cresol as a heat polymerization inhibitor and 3.07 g of triphenylphosphine as a reaction catalyst were charged, and reacted at a temperature of 98° C. until the acid value of the reaction solution was 0.5 mg·KOH/g or less, to obtain an epoxy carboxylate compound (theoretical molecular weight: 512.1).

And then, in this reaction solution, 719.4 g of γ-butyrolactone as a reaction solvent and 654.3 g of PMDA (pyromellitic acid anhydride manufactured by Degussa AG; molecular weight: 218.1) were charged and reacted at 98° C. for 10 hours to obtain a resin solution containing 70% energy ray-curable aqueous alkaline solution-soluble resin (this solution is referred to as (b-2) (acid anhydride)). The acid value was measured, resulting in 134 mg·KOH/g (solid acid value).

### Synthesis Example 5

### Synthesis (Esterification) Energy Ray-Curable Aqueous Alkaline Solution-Soluble Resin (b-4)

In a 5 L flask equipped with a stirring device, a circulation tube and a thermometer, 736.0 g of RE310S (bifunctional bisphenol A type epoxy resin manufactured by Nippon Kayaku Co., Ltd.; epoxy equivalent: 184 g/equivalent) as a bisphenol A type epoxy compound, 288.24 g of acrylic acid (manufactured by Nippon Shokubai Co., Ltd.; molecular weight: 72.06), 3.07 g of 2,6-ditertiary butyl-p-cresol as a heat polymerization inhibitor, and 3.07 g of triphenylphosphine as a reaction catalyst, and reacted at a temperature of 98° C. until the acid value of reaction solution was 0.5 mg·KOH/g or less to obtain an epoxy carboxylate compound (theoretical molecular weight: 512.1).

And then, in this reaction solution, 662.9 g of γ-butyrolactone as a reaction solvent and 218.1 g of PMDA (pyromellitic acid anhydride manufactured by Degussa AG, molecular weight: 218.1) as were charged and reacted at 98° C. for 10 hours. In addition, 304.3 g of THPA (tetrahydrophthalic anhydride manufactured by New Japan Chemical Co., Ltd.; molecular weight: 152.2) was charged therein and reacted at 98° C. for 5 hours to obtain a resin solution containing 70% energy ray-curable aqueous alkaline solution-soluble resin (this solution is referred to as (b-4) (terminal: carboxy group)). The acid value was measured, resulting in 145 mg·KOH/g (solid acid value).

### Synthesis Example 6

### Synthesis (Urethanation) of Energy Ray-Curable Aqueous Alkaline Solution-Soluble Resin (b-1b)

In a 5 L flask equipped with a stirring device, a circulation tube and a thermometer, 368.0 g of RE310S (bifunctional bisphenol A type epoxy resin manufactured by Nippon Kayaku Co., Ltd.; epoxy equivalent: 184 g/equivalent) as a bisphenol A type epoxy compound, 144.1 g of acrylic acid (manufactured by Nippon Shokubai Co., Ltd.; molecular weight: 72.06), 1.54 g of 2,6-ditertiary butyl-p-cresol as a heat polymerization inhibitor and 1.54 g of triphenylphosphine as a reaction catalyst were charged and reacted at a temperature of 98° C. until the acid value of the reaction solution was 0.5 mg·KOH/g or less, to obtain an epoxy carboxylate compound (theoretical molecular weight: 512.1).

And then, to this reaction solution, 601.3 g of γ-butyrolactone as a reaction solvent and 335.3 g of dimethylol propionic acid (manufactured by Trimet Products Group; molecular weight: 134.16) were added and the liquid temperature was raised to 45° C. To this solution, 555.7 g of isophorone diisocyanate (manufactured by Degussa Huels Ltd.; molecular weight: 222.28) was gradually added dropwise so that the reaction temperature was not over 65° C. After completion of the dropwise addition, the temperature was raised to 80° C., and the reaction was carried out for 8 hours until absorption around 2250 cm⁻¹ was not observed by infrared absorption spectrum measurement. Further the reaction was carried out at a temperature of 98° C. for 2 hours to obtain a resin solution containing 70% energy ray-curable aqueous alkaline solution-soluble resin (this solution is referred to as (b-1b) (terminal: hydroxy group)). The acid value was measured, resulting in 100 mg·KOH/g (solid acid value).

### Synthesis Example 7

### Synthesis (Urethanation) of Energy Ray-Curable Aqueous Alkaline Solution-Soluble Resin (b-3)

In a 5 L flask equipped with a stirring device, a circulation tube and a thermometer, 368.0 g of RE310S (bifunctional bisphenol A type epoxy resin manufactured by Nippon Kayaku Co., Ltd.; epoxy equivalent: 184 g/equivalent) as a bisphenol A type epoxy compound, 144.1 g of acrylic acid (manufactured by Nippon Shokubai Co., Ltd., molecular weight: 72.06), and 1.54 g of 2,6-ditertiary butyl-p-cresol as a heat polymerization inhibitor and 1.54 g of triphenylphosphine as a reaction catalyst, and reacted at a temperature of 98° C. until the acid value of the reaction solution was 0.5 mg·KOH/g or less to obtain an epoxy carboxylate compound (theoretical molecular weight: 512.1).

And then, to this reaction solution, 562.8 g of γ-butyrolactone and 134.1 g of dimethylol propionic acid (manufactured by Trimet Products Group; molecular weight: 134.16) as reaction solvents was added and the solution was raised to 45° C. in temperature. To this solution, 666.8 g of isophorone diisocyanate (manufactured by Degussa Huels Ltd.; molecular weight: 222.28) was gradually added dropwise so that the reaction temperature was not over 65° C. After completion of the dropwise addition, the temperature was raised to 80° C., and the reaction was carried out for 8 hours until absorption reduction around 2250 cm⁻¹ was not observed by infrared absorption spectrum measurement. Further the reaction was carried out at a temperature of 98° C. for 2 hours to obtain a resin solution containing 70% energy ray-curable aqueous alkaline solution-soluble resin (this solution is referred to as (b-3) (terminal: isocyanate group)). The acid value was measured, resulting in 43 mg·KOH/g (solid acid value).

### Example 1

### Synthesis (Esterification) of Photosensitive, Aqueous Alkaline Solution-Soluble Polyimide Resin (A-1)

In a 1 L flask equipped with a stirring device, a circulation tube and a thermometer, 48.6 g of γ-butyrolactone as a reaction solvent, 77.7 g of (a-1) obtained in Synthesis Example 1 and 281.8 g of (b-1a) obtained in Synthesis Example 3 were charged and reacted at 98° C. for 8 hours to obtain a resin solution containing 55% photosensitive, aqueous alkaline solution-soluble polyimide resin (theoretical acryl equivalent: 374) (this solution is called (A-1)). The acid value was measured, resulting in 102 mg·KOH/g (solid acid value). The weight average molecular weight as polystyrene was 29,000.

### Example 2

### Synthesis (Esterification) of Photosensitive, Aqueous Alkaline Solution-Soluble Polyimide Resin (A-2)

In a 1 L flask equipped with a stirring device, a circulation tube and a thermometer, 18.3 g of γ-butyrolactone as a reaction solvent, 100.1 g of (a-1) obtained in Synthesis Example 1 and 200.4 g of (b-1b) obtained in Synthesis Example 6 were charged and reacted at 98° C. for 8 hours to obtain a resin solution containing 55% photosensitive, aqueous alkaline solution-soluble polyimide resin (theoretical acryl equivalent: 438) (this solution is referred to as (A-2)). The acid value was measured, resulting in 83 mg·KOH/g (solid acid value). The weight average molecular weight as polystyrene was 34,000.

### Example 3

### Synthesis (Amidation) of Photosensitive, Aqueous Alkaline Solution-Soluble Polyimide Resin (A-3)

In a 1 L flask equipped with a stirring device, a circulation tube and a thermometer, 6.6 g of γ-butyrolactone as a reaction solvent, 161.7 g of (a-2) obtained in Synthesis Example 2 and 239.8 g of (b-2) obtained in Synthesis Example 4 were charged and reacted at 45° C. for 8 hours to obtain a resin solution containing 55% photosensitive, aqueous alkaline solution-soluble polyimide resin (theoretical acryl equivalent: 1122) (this solution is referred to as (A-3)). The acid value was measured, resulting in 151 mg·KOH/g (solid acid value). The weight average molecular weight as polystyrene was 29,000.

### Example 4

### Synthesis (Imidization) of Photosensitive, Aqueous Alkaline Solution-Soluble Polyimide Resin (A-4)

In a 3 L flask equipped with a stirring device, a circulation tube and a thermometer, 187.6 g of γ-butyrolactone as a reaction solvent, 1228.0 g of (a-1) obtained in Synthesis Example 1 and 187.6 g of (b-3) obtained in Synthesis Example 7 were charged and reacted at 120° C. for 8 hours to obtain a resin solution containing 35% photosensitive, aqueous alkaline solution-soluble polyimide resin (theoretical acryl equivalent: 1403) (this solution is referred to as (A-4)). The acid value was measured, resulting in 12 mg·KOH/g (solid acid value). The weight average molecular weight as polystyrene was 39,000.

### Example 5

### Synthesis (Amidation) of Photosensitive, Aqueous Alkaline Solution-Soluble Polyimide Resin (A-5)

In a 3 L flask equipped with a stirring device, a circulation tube and a thermometer, 221.0 g of γ-butyrolactone as a reaction solvent, 1161.2 g of (a-2) obtained in Synthesis Example 2 and 221.0 g of (b-4) obtained in Synthesis Example 5 were charged and reacted at 120° C. for 8 hours to obtain a resin solution containing 35% photosensitive, aqueous alkaline solution-soluble polyimide resin (theoretical acryl equivalent: 2806) (this solution is referred to as (A-5)). The acid value was measured, resulting in 20 mg·KOH/g (solid acid value). The weight average molecular weight as polystyrene was 42,000.

### Example 6

### Synthesis (Ureation) of Photosensitive, Aqueous Alkaline Solution-Soluble Polyimide Resin (A-6)

In a 3 L flask equipped with a stirring device, a circulation tube and a thermometer, 187.6 g of γ-butyrolactone as a reaction solvent, 426.4 g of (a-2) obtained in Synthesis Example 2 and 187.6 g of (b-3) obtained in Synthesis Example 7 were charged and reacted at 90° C. for 7 hours to obtain a resin solution containing 35% photosensitive, aqueous alkaline solution-soluble polyimide resin (theoretical acryl equivalent: 1403) (this solution is referred to as (A-6)). The acid value was measured, resulting in 22 mg·KOH/g (solid acid value). The weight average molecular weight as polystyrene was 40,000.

### Comparative Example 1

In a 3 L flask equipped with a stirring device and a circulation tube, 860.0 g of EOCN-103S (polyfunctional cresol novolak-type epoxy resin; epoxy equivalent: 215.0 g/equivalent) manufactured by Nippon Kayaku Co., Ltd. as an epoxy compound having two or more epoxy groups in a molecule, 288.3 g of acrylic acid (molecular weight: 72.06) as a monocarboxylic acid compound having an ethylenically unsaturated group in a molecule, 492.1 g of carbitol acetate as a reaction solvent, 4.921 g of 2,6-di-tert-butyl-p-cresol as a heat polymerization inhibitor and 4.921 g of triphenylphosphine as a reaction catalyst were charged and reacted at a temperature of 98° C. until the acid value of the reaction solution was 0.5 mg·KOH/g or less, to obtain an epoxy carboxylate compound.

And then, in this reaction solution, 169.8 g of carbitol acetate as a reaction solvent and 201.6 g of tetrahydrophthalic anhydride as a polybasic acid anhydride were charged and reacted at 95° C. for 4 hours to obtain a resin solution containing 67% aqueous alkaline solution-soluble resin (this solution is referred to as R-1). The acid value was measured, resulting in 69.4 mg·KOH/g (solid acid value: 103.6 mg·KOH/g). The weight average molecular weight as polystyrene was 9,000.

### Examples 7, 8 and 9 and Comparative Example 2

The above (A-1), (A-2), (A-3) and (R-1) obtained respectively In Example 1, Example 2, Example 3 and Comparative Example 1 were respectively mixed in the mixing ratio shown in Table 1 and kneaded by a three-roller mill to obtain photosensitive resin compositions of the present invention. These were each coated on a printed substrate and an imide film by a screen printing method so that the dried films' thickness was 15 to 25 μm and the coated films were dried for 30 minutes in a hot air drying oven at 80° C. And then, using an ultraviolet exposure unit (ORC Manufacturing Co., Ltd; Model HMW-680GW), ultraviolet rays were irradiated through a mask with a circuit pattern formed. And then, spray development was performed with a 1% aqueous sodium carbonate solution to remove resin on the ultraviolet ray unirradiated region. After washing with water and drying, the printed substrates were heated for 60 minute in a hot air drying oven at 150° C. The cured products obtained were, as described later, tested for developability, resolution properties, photosensitivity, substrate warping, flexibility, adhesion properties, solvent resistance, acid resistance, heat resistance, gold plating resistance, PCT resistance and thermal shock resistance. Their results are shown in Table 2. In this regard, the test methods and the evaluation methods are as follows.

(Tack properties) The films coated on the substrates and dried were rubbed with absorbent cotton and then evaluated for tack properties of the films.
∘ . . . Absorbent cotton is not stuck.
x . . . Waste of absorbent cotton is stuck.
(Developability) The following evaluation criteria were used.
∘ . . . In development, ink is completely removed and development can be carried out.
x . . . In development, there are some parts not developed.
(Resolution properties) A 50 μm negative pattern was closely contacted on the coated films after drying, which were then irradiated by exposure to ultraviolet rays in an integrated light quantity of 500 mJ/cm². And then, they were developed with a 1% aqueous sodium carbonate solution for 40 minutes at a spray pressure of 2.0 kg/cm² and their transfer patterns were observed with a microscope. The following criteria were used.
∘ . . . Pattern-edge is a straight line and resolution can be performed.
x . . . Transfer pattern is peeled or pattern-edge is jagged.
(Photosensitivity) A 21 Step Tablet (manufactured by Kodak Japan, Ltd.) was closely contacted on the coated films after drying, which were then irradiated by exposure to ultraviolet rays at an integrated light quantity of 500 mJ/cm². And then they were developed with a 1% aqueous sodium carbonate solution for 40 seconds at a spray pressure of 2.0 kg/cm² and the number of the steps remained undeveloped was checked.
(Substrate warping) Polyimide film was used as a substrate and the following criteria were used.
∘ . . . No warp is observed on film.
Δ . . . Film is slightly warped.
x . . . Warp is observed on film.
(Flexibility) The cured films on the films were bent at 180 degrees and observed. The following criteria were used.
∘ . . . No crack is observed on film surface.
x . . . Film surface is cracked.
(Adhesion properties) In accordance with JIS K5400, a grid having a hundred of 1 mm squares was formed on their test pieces and peeling test was conducted with a cellophane-tape. The peeling states of the grids were observed and evaluated according to the following criteria.
∘ . . . No peeling is observed.
x . . . Peeling is observed.
(Solvent resistance) The test pieces were immersed in isopropyl alcohol at room temperature for 30 minutes. After checking that they had no abnormal appearance, peeling test was conducted with a cellophane-tape and evaluation was conducted according to the following criteria.
∘ . . . Coated film has no abnormal appearance, no bulge or no peeling.
x . . . Coated film has bulge or peeling.
(Acid resistance) The test pieces were immersed in a 10% aqueous hydrochloric acid solution at room temperature for 30 minutes. After checking that they had no abnormal appearance, peeling test was conducted with a cellophane-tape and evaluation was conducted according to the following criteria.
∘ . . . Coated film has no abnormal appearance, no bulge or no peeling.
x . . . Coated film has bulge or peeling.
(Heat resistance) The test pieces were coated with rosin-based flux and immersed in a solder bath at 260° C. for 30 seconds. This procedure was defined as 1 cycle and 3 cycles were repeated. They were left to be cooled to room temperature, and then peeling test was conducted with a cellophane-tape and evaluation was conducted according to the following criteria.
∘ . . . Coated film has no abnormal appearance, no bulge or no peeling.
x . . . Coated film has bulge or peeling.
(Gold plating resistance) The test substrates were immersed in an acidic degreasing solution (manufactured by Nippon Mac Dermid Co., Ltd; 20 vol % aqueous solution of Metex L-5B) at 30° C. for 3 minutes and then washed with water. Subsequently, they were immersed in a 14.4 wt % aqueous ammonium persulfate solution at room temperature for 3 minutes and then washed. In addition, the test substrates were immersed in a 10 vol % aqueous sulfuric acid solution at room temperature for 1 minute and then washed. Next, These substrates were immersed in a catalyst solution (manufactured by Meltex Inc.; 10 vol % aqueous solution of metal plate activator 350) at 30° C. for 7 minutes, washed with water, immersed in a nickel plating solution (manufactured by Meltex Inc.; 20 vol % aqueous solution of Melplate Ni-865M, pH 4.6) at 85° C. for 20 minutes, nickel-plated, and then immersed in a 10 vol % sulfuric acid aqueous solution at room temperature for 1 minute, followed by washing with water. Subsequently, the test substrates were immersed in a gold plating solution (manufactured by Meltex Inc.; aqueous solution of 15 vol % of Aurolectroless UP and 3 vol % of gold potassium cyanide, pH 6) at 95° C. for 10 minutes, nonelectrolytic gold-plated and then washed with water. They were further immersed in hot water at 60° C. for 3 minutes, washed with water and dried. A cellophane adhesive tape was adhered to the obtained substrates for evaluation of nonelectrolytic gold plating and the states were observed when the tape was peeled.
∘ . . . Abnormality is not observed at all.
x . . . Peeling is slightly observed.
(PCT resistance) The test substrates were left at 121° C. under two atmospheres in water for 96 hours and then checked that they had no abnormal appearance. Peeling test was conducted on them using a cellophane-tape and evaluation was conducted according to the following criteria (PCT: Pressure Cooker Test).
∘ . . . Coated film has no abnormal appearance, no bulge or no peeling.
x . . . Coated film has bulge or peeling.
(Thermal shock resistance) A thermal history of −55° C./30 minutes and 125° C./30 minutes applied to the test pieces was defined as 1 cycle. After 1,000 cycles were repeated, the test pieces were observed with a microscope and evaluated according to the following criteria.
∘ . . . Cracking does not occur on coated film.
x . . . Cracking occurs on coated film.

TABLE 1

| | | | Comparative |
|---|---|---|---|
| Examples | | | Example |
| 7 | 8 | 9 | 2 |

Resin solution (A)

| | | | | |
|---|---|---|---|---|
| A-1 | 50.00 | | | |
| A-2 | | 50.00 | | |
| A-3 | | | 50.00 | |
| R-1 | | | | 42.30 |

Cross-linking agent (C)

| | | | | |
|---|---|---|---|---|
| DPCA-60 *1 | 2.75 | 2.75 | 2.75 | 2.75 |

Photopolymerization initiator (B)

| | | | | |
|---|---|---|---|---|
| IRGACURE - 907 *2 | 1.50 | 1.50 | 1.50 | 1.50 |
| DETX-S *3 | 0.30 | 0.30 | 0.30 | 0.30 |
| ERA *4 | 0.30 | 0.30 | 0.30 | 0.30 |

Curing agent (D)

| | | | |
|---|---|---|---|
| NC-3000H *5 | 16.90 | 25.40 | 16.90 |

Heat-curing catalyst

| | | | |
|---|---|---|---|
| Melamine | 0.70 | 0.70 | 0.70 |

Additives

| | | | | |
|---|---|---|---|---|
| BYK-405 *6 | 0.30 | 0.30 | 0.30 | 0.30 |
| KS-66 *7 | 0.73 | 0.73 | 0.73 | 0.73 |

Solvent

| | | | | |
|---|---|---|---|---|
| γ-Butyrolactone | 4.63 | 4.63 | 4.63 | 4.63 |

*1 ε-Caprolactone-modified dipentaerythritol hexaacrylate: manufactured by Nippon Kayaku Co., Ltd.
*2 2-Methyl-(4-(methylthio)phenyl)-2-morpholino-1-propane: manufactured by Vantico.
*3 2,4-Diethylthioxanthone: manufactured by Nippon Kayaku Co., Ltd.
*4 4-Dimethylaminoethylbenzoate: manufactured by Nippon Kayaku Co., Ltd.
*5 Bifunctional biphenol type epoxy resin: manufactured by Nippon Kayaku Co., Ltd.
*6 Thixo-agent, a leveling agent: manufactured by BYK Japan KK.
*7 Antifoaming agent: manufactured by Shin-Etsu Chemical Co., Ltd.

TABLE 2

| | | | | Comparative |
|---|---|---|---|---|
| | Examples | | | Example |
| Evaluation Items | 7 | 8 | 9 | 2 |
| Tack properties | ∘ | ∘ | ∘ | ∘ |
| Developability | ∘ | ∘ | ∘ | ∘ |
| Resolution properties | ∘ | ∘ | ∘ | ∘ |
| Photosensitivity | 7 | 6 | 6 | 5 |
| Substrate warping | Δ | ∘ | ∘ | x |
| Flexibility | ∘ | ∘ | ∘ | x |
| Adhesion properties | ∘ | ∘ | ∘ | x |
| Solvent resistance | ∘ | ∘ | ∘ | ∘ |
| Acid resistance | ∘ | ∘ | ∘ | ∘ |
| Heat resistance | ∘ | ∘ | ∘ | x |
| Gold plating resistance | ∘ | ∘ | ∘ | ∘ |
| PCT resistance | ∘ | ∘ | ∘ | x |
| Thermal shock resistance | ∘ | ∘ | ∘ | x |

### Examples 10, 11, and 12 and Comparative Example 3

The above (A-4), (A-5), (A-6) and (a-1) obtained respectively in Example 4, Example 5, Example 6 and Synthesis Example 1 were respectively mixed in the mixing ratio shown in Table 3 and kneaded by a three-roller mill to obtain photosensitive resin compositions of the present invention. These were coated each on a printed substrate and an imide film by a screen printing method so that the dried films' thickness was 15 to 25 μm and the coated films were dried for 30 minutes in a hot air drying oven at 80° C. And then, using an ultraviolet exposure unit (ORC Manufacturing Co., Ltd; Model HMW-680GW), ultraviolet rays were irradiated through a mask with a circuit pattern formed. And then, spray development was performed with a 1% aqueous sodium hydroxide solution to remove resin on the ultraviolet ray unirradiated region. After washing with water and drying, the printed substrates were heated for 60 minute in a hot air drying oven at 150° C. The cured products obtained were, as described later, tested for tack properties, developability, resolution properties, substrate warping, flexibility, adhesion properties, solvent resistance, acid resistance, heat resistance, gold plating resistance, PCT resistance and thermal shock resistance. Their results are shown in Table 4. In this regard, the test methods and the evaluation methods are as described above.

TABLE 3

| | | | Comparative |
|---|---|---|---|
| Examples | | | Example |
| 10 | 11 | 12 | 3 |

Resin solution (A)

| | | | | |
|---|---|---|---|---|
| A-4 | 50.00 | | | |
| A-5 | | 50.00 | | |
| A-6 | | | 50.00 | |
| a-1 | | | | 50.00 |

Photoacid-generating agent (E)

| | | | | |
|---|---|---|---|---|
| NAC-5 *8 | 2.63 | 2.63 | 2.63 | 2.63 |

Solvent

| | | | | |
|---|---|---|---|---|
| γ-Butyrolactone | 4.63 | 4.63 | 4.63 | 4.63 |

Note:
*8 1,2-Naphthoquinone (2) diazide-5-sulfonic acid chloride: manufactured by Toyo Gosei Co., Ltd.

TABLE 4

| | | | | Comparative |
|---|---|---|---|---|
| | Examples | | | Example |
| Evaluation Items | 10 | 11 | 12 | 3 |
| Tack Properties | ∘ | ∘ | ∘ | ∘ |
| Developability | ∘ | ∘ | ∘ | ∘ |
| Resolution Properties | ∘ | ∘ | ∘ | ∘ |
| Substrate Warping | ∘ | ∘ | ∘ | Δ |
| Flexibility | ∘ | ∘ | ∘ | ∘ |
| Adhesion Properties | ∘ | ∘ | ∘ | ∘ |
| Solvent Resistance | ∘ | ∘ | ∘ | ∘ |
| Acid Resistance | ∘ | ∘ | ∘ | ∘ |
| Heat Resistance | ∘ | ∘ | ∘ | ∘ |
| Gold Plating Resistance | ∘ | ∘ | ∘ | ∘ |
| PCT Resistance | ∘ | ∘ | ∘ | x |
| Thermal Shock Resistance | ∘ | ∘ | ∘ | x |

As is clear from the above results, the photosensitive, aqueous alkaline solution-soluble polyimide resin composition of the present invention is excellent in tack properties, developability, resolution properties, solder heat resistance, chemical resistance, gold plating resistance, flexibility, adhesion properties, PCT resistance, thermal shock resistance and the like, do not allow cracking on the surfaces of the cured products thereof, and have less warping on its substrate even if a thin-filmed substrate is used.

The alkali-soluble polyimide resin (A), the photosensitive resin composition using the same and cured products thereof have excellent photosensitivity in formation of coated films by exposure-curing with ultraviolet rays; their cured products obtained have flexibility, adhesion properties, solvent resistance, acid resistance, heat resistance, gold plating resistance and the like which are sufficiently satisfying; and in particular, the alkali-soluble polyimide resin (A) is suitable for photosensitive resin compositions for printed wiring boards.

1. A photosensitive, aqueous alkaline solution-soluble polyimide resin (A) obtained by reacting a polyimide resin (a), which is obtained by reaction of a tetracarboxylic acid dianhydride with a diamine compound, with an energy ray-curing type aqueous alkaline solution-soluble resin (b).

2. The photosensitive, aqueous alkaline solution-soluble polyimide resin (A) according to claim 1, wherein the polyimide resin (a) is obtained by carrying out reaction of a tetracarboxylic acid dianhydride with a diamine compound in the presence of a lactone and a base as catalysts.

3. The photosensitive, aqueous alkaline solution-soluble polyimide resin (A) according to claim 1 or 2, characterized in that the polyimide resin (a) has a phenol hydroxy group.

4. The photosensitive, aqueous alkaline solution-soluble polyimide resin (A) according to any one of claims 1 to 3, characterized in that the energy ray-curing type aqueous alkaline solution-soluble resin (b) has a hydroxy group, an isocyanate group or a carboxy group at a terminal, or is an acid anhydride.

5. The photosensitive, aqueous alkaline solution-soluble polyimide resin (A) according to any one of claims 1 to 4, wherein the energy ray-curing type aqueous alkaline solution-soluble resin (b) (hereinafter, referred to as resin (b)) is any of the following (1), (2) or (3):
(1) A resin (b) obtained by reacting a reaction product (c) of an epoxy compound having two epoxy groups with a monocarboxylic acid compound having an ethylenically unsaturated group, with a tetracarboxylic acid dianhydride (d);
(2) A resin (b) obtained by reacting a reaction product (c) of an epoxy compound having two epoxy groups with a monocarboxylic acid compound having an ethylenically unsaturated group, with a monocarboxylic acid compound (e) having two hydroxy groups in a molecule and a diisocyanate compound (f); or
(3) A resin (b) obtained by reacting a reaction product (c) of an epoxy compound having two epoxy groups with a monocarboxylic acid compound having an ethylenically unsaturated group, with tetracarboxylic acid dianhydride (d) and then a dicarboxylic acid monoanhydride.

6. The photosensitive, aqueous alkaline solution-soluble polyimide resin (A) according to any one of claims 1 to 5, wherein the weight average molecular weight as polystyrene is 10,000 to 400,000.

7. A negative-type, photosensitive, aqueous alkaline solution-soluble polyimide resin composition characterized by containing the photosensitive, aqueous alkaline solution-soluble polyimide resin (A) according to any one of claims 1 to 6, a photopolymerization initiator (B), a cross-linking agent (C) as an optional component and further a curing agent (D) as an optional component.

8. A positive-type, photosensitive, aqueous alkaline solution-soluble polyimide resin composition characterized by containing the photosensitive, aqueous alkaline solution-soluble polyimide resin (A) according to any one of claims 1 to 6 and a photoacid-generating agent (E).

9. A cured product of the photosensitive, aqueous alkaline solution-soluble polyimide resin composition according to claim 7 or 8.

10. A substrate having a layer of the cured product according to claim 9.

11. A polyimide resin solution containing a photosensitive, aqueous alkaline solution-soluble polyimide resin (A) obtained by reacting a polyimide resin (a) which is obtained by reaction of a tetracarboxylic acid dianhydride with a diamine compound, with an energy ray-curing type aqueous alkaline solution-soluble resin (b), and a solvent.

12. The polyimide resin solution according to claim 11, wherein the energy ray-curing type aqueous alkaline solution-soluble resin (b) is:
(i) A resin (b) obtained by reacting an epoxy (meth)acrylate with a tetracarboxylic acid dianhydride (d);
(ii) A resin (b) obtained by reacting an epoxy (meth)acrylate with a monocarboxylic acid compound (e) having two hydroxy groups in a molecule and a diisocyanate compound (f); or
(iii) A resin (b) obtained by reacting an epoxy (meth)acrylate with a tetracarboxylic acid dianhydride (d) and then dicarboxylic acid monoanhydride.
